(19) United States
(12) Patent Application Publication
(10) Pub. No.: US 2024/0021427 A1
(43) Pub. Date: Jan. 18, 2024

(54) METHOD OF FORMING FILM AND METHOD OF MANUFACTURING SEMICONDUCTOR DEVICE USING THE SAME

(71) Applicant: Samsung Electronics Co., Ltd., Suwon-si (KR)

(72) Inventors: Jungmin Park, Suwon-si (KR); Hanjin Lim, Suwon-si (KR); Jaesoon Lim, Suwon-si (KR); Hyungsuk Jung, Suwon-si (KR)

(21) Appl. No.: 18/201,251

(22) Filed: May 24, 2023

(30) Foreign Application Priority Data
Jul. 15, 2022 (KR) 10-2022-0087593

(51) Int. Cl. H01L 21/02; H01L 21/324; C23C 16/04; C23C 16/56

(52) U.S. Cl. CPC H01L 21/02205; H01L 21/0228; H01L 21/324; H01L 21/022; C23C 16/04; C23C 16/56; H01L 21/02112

(57) ABSTRACT

A method of forming a thin film is provided, the method including: an operation of supplying a precursor to a substrate, to selectively adsorb the precursor to a partial region of a surface of the substrate; an operation of performing a region-selective annealing by irradiating microwaves onto the substrate; and an operation of supplying a reactant to react with the precursor adsorbed on the substrate to form a thin film unit layer, wherein the microwave irradiated onto the substrate induces vibrations in at least a portion of the precursor so that the partial region of the surface of the substrate on which the precursor is adsorbed is locally heated.

### CROSS-REFERENCE TO RELATED APPLICATION

This application claims the priority and benefit of Korean Patent Application No. 10-2022-0087593, filed on Jul. 15, 2022, with the Korean Intellectual Property Office, the inventive concept of which is incorporated herein by reference.

### BACKGROUND

### 1. Field

The present inventive concept relates to a method of forming a thin film and a method of manufacturing a semiconductor device using the same.

### 2. Description of Related Art

According to the development of the electronic industry and the needs of users, electronic devices are becoming miniaturized and higher in performance. Accordingly, semiconductor devices used in electronic devices are also required to be highly integrated and high-performance. In order to manufacture a highly-scaled semiconductor device, it is required to implement finer patterns. Accordingly, a manufacturing process of the semiconductor device becomes more complicated and the manufacturing cost increases.

### SUMMARY

An aspect of the present inventive concept is to provide a method of forming a thin film having a simple manufacturing process and improved reliability by using a region-selective annealing process by microwave irradiation, and a method of manufacturing a semiconductor device using the same.

According to an aspect of the present inventive concept, a method of forming a thin film may be provided, the method including: supplying a precursor to a substrate, to selectively adsorb the precursor to a partial region of a surface of the substrate; performing a region-selective annealing by irradiating microwaves onto the substrate; and supplying a reactant to react with the precursor adsorbed on the substrate to form a thin film unit layer, wherein the microwave irradiated onto the substrate induces vibrations in at least a portion of the precursor so that the region of the surface of the substrate on which the precursor is adsorbed is locally heated.

According to an aspect of the present inventive concept, a method of forming a thin film may be provided, the method including: a precursor supply operation of supplying a precursor to a substrate positioned in a chamber; a precursor purge operation of purging the chamber after the precursor supply operation; a region-selective annealing operation of locally heating a partial region of a surface of the substrate on which the precursor is selectively adsorbed by irradiating microwaves into the chamber; and a reactant supply operation of supplying a reactant to the chamber to react with the precursor adsorbed on the substrate, wherein, after the reactant supply operation, a unit cycle process including a reactant purge operation of purging the chamber is repeatedly performed a plurality of times, to selectively form a thin film on the substrate.

According to an aspect of the present inventive concept, a method of manufacturing a semiconductor device may be provided, the method including: an operation of forming a lower film; and an operation of region-selectively forming an upper film on the lower film, wherein the operation of forming the upper film includes repeatedly performing a unit cycle process a plurality of times, wherein the unit cycle process includes a precursor supply operation of supplying a precursor to the lower film, to adsorb the precursor to a partial region of a surface of the lower film; a region-selective annealing operation of locally heating the partial region of the surface of the lower film on which the precursor is adsorbed, by irradiating microwaves to induce vibrations in at least a portion of the precursor; and an operation of supplying a reactant to react with the precursor to form a thin film unit layer of the upper film.

### BRIEF DESCRIPTION OF DRAWINGS

The above and other aspects, features, and advantages of the present inventive concept will be more clearly understood from the following detailed description taken in conjunction with the accompanying drawings, in which:

FIG. 1 is a schematic diagram illustrating an apparatus for manufacturing a thin film according to example embodiments;

FIG. 2 is a flowchart illustrating a method of forming a thin film according to an example embodiment according to a process sequence;

FIGS. 3A and 3B are manufacturing process diagrams illustrating a method of forming a thin film using an apparatus for manufacturing a thin film according to example embodiments;

FIGS. 4A and 4B are diagrams illustrating an upper film region-selectively formed on a lower film by an apparatus for manufacturing a thin film according to example embodiments;

FIG. 5 is a cross-sectional view illustrating an information storage structure of a semiconductor device according to example embodiment;

FIG. 6A is a plan view of a semiconductor device according to example embodiments, and FIG. 6B is a cross-sectional view of a semiconductor device according to example embodiments;

FIG. 7 is an enlarged view of area ‘A’ of FIG. 6B;

FIG. 8 is a cross-sectional view of a semiconductor device according to example embodiments;

FIG. 9 is an enlarged view of area ‘B’ of FIG. 8;

FIG. 10 is a flowchart illustrating a semiconductor device according to an example embodiment according to a process sequence; and

FIGS. 11A, 11B, 12A, 12B, 13A, 13B, 14, and 15 are diagrams illustrating a method of manufacturing a semiconductor device according to example embodiments.

### DETAILED DESCRIPTION

Hereinafter, preferred embodiments of the present inventive concept will be described with reference to the accompanying drawings. Hereinafter, terms such as ‘an upper side, ‘an upper portion’, ‘an upper surface’, a lower side, a lower portion, a lower surface, and the like, may be understood as referring to the drawings, except where otherwise indicated by reference numerals.

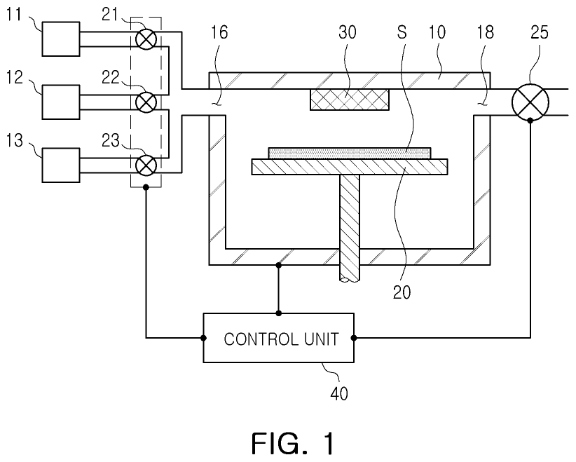

FIG. 1 is a schematic diagram illustrating an apparatus for manufacturing a thin film according to example embodiments.

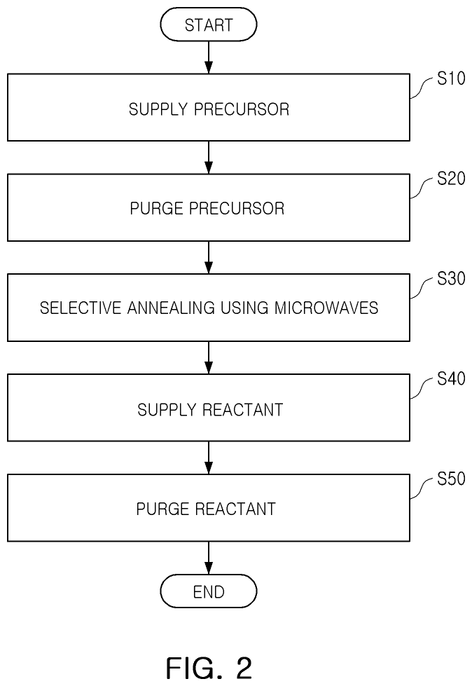

FIG. 2 is a flowchart illustrating a method for forming a thin film according to example embodiments according to a process sequence.

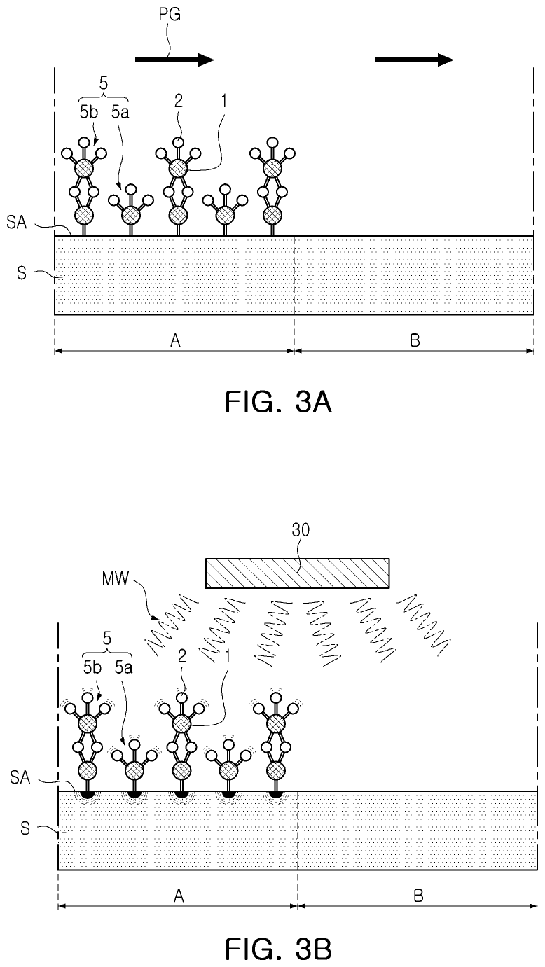

FIGS. 3A and 3B are manufacturing process diagrams illustrating a method of forming a thin film using an apparatus for manufacturing a thin film according to example embodiments.

A method of forming a thin film on a substrate according to a method of forming a thin film of FIG. 2 using the apparatus for manufacturing a thin film of FIG. 1 will be described. FIG. 3A illustrates a state of a surface (SA) of a substrate S in a precursor supply operation (S10), and FIG. 3B illustrates a state of a surface (SA) of a substrate S in a region-selective annealing step (S30) using microwaves. The apparatus for manufacturing a thin film of FIG. 1 may be a facility capable of performing an atomic layer deposition (ALD) process or a molecular layer deposition (MLD) process (or a combination thereof).

First, a substrate S may be loaded onto a stage 20 in a chamber 10 having a gas inlet 16 and a gas outlet 18.

The substrate S may be a semiconductor substrate, a metal substrate, a glass substrate, or a flexible substrate. For example, the flexible substrate may be a polymer substrate, for example, a PET (polyethylene terephthalate) or PI (polyimide) substrate. A protective layer (not shown) such as an insulating film, or the like, covering the substrate S may be formed on the substrate S, or a device component such as a semiconductor pattern, or the like, may be formed, and a protective layer (not shown) such as an insulating film, or the like, covering the device component may be formed. The chamber 10 may be a chamber in which the substrate S is loaded to perform an atomic layer deposition (ALD) process or a molecular layer deposition (MLD) process.

Before loading the substrate S, the chamber 10 may be heated to a deposition temperature by the control unit and maintained. The deposition temperature may be 20 to 150° C., 25 to 120° C., 30 to 100° C., 35 to 80° C., 40 to 60° C., or 45 to 55° C. The gas outlet 18 may be connected to a vacuum pump.

Next, by closing all gas inlet valves 21, 22, and 23 connected to the gas inlet 16 and opening a gas outlet valve 25 connected to the gas outlet 18, an inside of the chamber can be made into a vacuum state. Next, a thin film may be region-selectively formed on the substrate S by performing the following operations.

A precursor supply operation (S10) of supplying a precursor gas into the chamber may be performed. For example, in a state in which the precursor gas control valve 21 is opened and the gas outlet valve 25 is closed, precursor gas may be supplied from a precursor storage unit 11 into the chamber 10.

As illustrated in FIG. 3A, a precursor 5 may include a central atom 1 and a ligand 2 bound to the central atom 1. A plurality of ligands 2 may be connected to the central atom 1. The precursor 5 may include at least one of a monomer precursor 5a having one central atom 1 and a dimer precursor 5b having two central atoms 1. In one example, the precursor 5 has a metal ion (e.g. a transition metal ion) at its center with a number of other atoms, molecules or ions surrounding it (the ligands). The ligands can be attached to the central metal ion by dative covalent (coordinate) bonds. The dative covalent bond between the metal ion and ligands is a covalent bond formed by two atoms sharing a pair of electrons where both electrons come from the same atom. Also, as seen for example in precursor 5A, each ligand is monodentate (bonding a single time to the metal ion). However it is also possible to have a ligand that bonds more than once to the metal ion (polydentate) such as two bonds to the metal ion (bidentate), etc. As can be seen for example in precursor 5B, a ligand bonds to more than one metal (bridging).

The precursor 5 may be referred to as “ML.”. In “ML.”, “M” may be a central atom 1 of the precursor 5, “L” may be a ligand bound to the central atom 1 of the precursor and “n” is a number determined by “M” as the central atom 1 and “L” as the ligand 2, and may be, for example, any one value between 2 and 6.

“M”, the central atom 1, may include a metal. M″, the central atom 1, may include, for example any one of Be, B, Mg, Al, Ca, Sc, Ti, V, Cr, Mn, Fe, Co, Ni, Cu, Zn, Ga, Sr, Y, Zr, Nb, Mo, Tc, Ru, Rh, Pd, Ag, Cd, In, Sn, Ba, La, Hf, Ta, W, Re, Os, Ir, Pt, Au, Hg, Tl, Pb or Bi or two or more thereof. In another example, “M”, the central atom 1, may include a semiconductor material such as Si or Ge.

“L”, the ligand 2, may include a polar molecule or ion whose vibrations are induced by microwaves. The ligand 2 may be, for example, an anionic ligand or a neutral ligand. As an example, the microwaves induce vibrations so as to induce localized heating where the polar molecule (or ion) is present, with substantially no heating in areas where the polar molecule (or ion) is not present.

The anionic ligand (or when a plurality of the anion ligands are present, the anion ligands are independently present, respectively) may be a halogen such as hydrogen (H), fluoro (F), chloro (Cl), bromo (Br), iodo (I), or may be an alkoxy group having 1 to 10 carbon atoms, an aryl group having from 6 to 12 carbon atoms, an allyl group having from 3 to 15 carbon atoms, a dienyl group having from 4 to 15 carbon atoms, a cyclopentadienyl group having from 5 to 12 carbon atoms, a β-diketonato group having from 5 to 20 carbon atoms, a β-ketoiminato group having from 5 to 20 carbon atoms, or a β-diiminato group, an hydroxy (OH) group, or an amido (NH₂) group having from 5 to 20 carbon atoms or an amido group having from 1 to 10 carbon atoms, an imido group having from 1 to 10 carbon atoms, a carboxyl group having from 1 to 10 carbon atoms, an amidine group having from 1 to 10 carbon atoms, an acetamido group having from 1 to 10 carbon atoms, or a thiol group having from 1 to 10 carbon atoms.

The neutral ligand (or when a plurality of the neutral ligands are present, the neutral ligands are independently present, respectively) may be alkene having from 2 to 10 carbon atoms, alkyne having from 2 to 10 carbon atoms, alcohol having from 1 to 10 carbon atoms, an ether compound having from 2 to 10 carbon atoms, a ketone compound having from 3 to 10 carbon atoms, an aryl compound having from 6 to 12 carbon atoms, an allyl compound having from 3 to 15 carbon atoms, a diene compound having from 4 to 15 carbon atoms, a β-diketone compound having from 5 to 20 carbon atoms, a β-ketoimine compound having 5 to 20 carbon atoms, a β-diimine compound having from 5 to 20 carbon atoms, ammonia, an amine compound having from 1 to 10 carbon atoms, a thiol compound having from 1 to 10 carbon atoms, a thioether compound having from 2 to 10 carbon atoms, or a thioketone compound having from 2 to 10 carbon atoms.

In one example, at least a portion of the ligands 2 may be different from each other. At least one of the ligands 2 may include nitrogen or oxygen. For example, the ligands 2 may be independently an alkyl group, an alkenyl group, an alkynyl group, a halogen element, a cyclopentadienyl group, an amino group, an imino group, or an alkoxy group, respectively.

However, a structure of the precursor 5 is not limited to the illustrated, and a material of the precursor 5 may not be limited to the above-described ones. The structure and/or material of the precursor 5 may be variously changed according to the type of film to be deposited.

In the precursor supply operation S10, as illustrated in FIG. 3A, the precursor 5 provided by precursor gas PG may be deposited on a surface SA of the substrate S or a surface of a layer, pre-formed on the substrate S, by chemisorption and self-saturated reaction. The substrate S may have regions A and B having different surface properties for each area, and for example, the precursor 5 may be adsorbed to a region A of the surface SA of the substrate S, but may not be adsorbed to another region B. In one example, before the precursor supply operation (S10), an inhibitor may be provided on the region B of the substrate S. In one example, the precursor supply operation (S10) may be repeatedly performed at least once or more before the reactant supply operation (S40).

After the precursor supply operation (S10), a precursor purge operation (S20) of purging the chamber 10 may be performed. For example, by opening the purge gas control valve 22 and the gas outlet valve 25, purge gas in the purge gas storage unit 12 may flow onto the surface SA of the substrate S in the chamber 10 so that excess precursor gas, not adsorbed on the surface of the substrate S and reaction by-products generated by reaction between the precursor gas and the surface SA of the substrate S may be removed.

The purge gas is an inert gas, and the inert gas may include, for example, argon (Ar), nitrogen (N₂), or a combination thereof.

A region-selective annealing operation (S30) using microwaves in which a region (A) of the surface of the substrate S on which the precursor is adsorbed is locally heated by irradiating microwaves in the chamber 10 may be performed. For example, microwaves MW may be irradiated onto the surface SA of the substrate S from microwaves generator 30 provided in the chamber 10.

The microwave MW may be an electromagnetic wave having a frequency in a range of about 0.3 GHz to about 300 GHz. As illustrated in FIG. 3B, the microwave MW may induce vibrations in a portion of the precursor 5. For example, a ligand 2 of the precursor 5 may vibrate due to microwave MW irradiation. Accordingly, a partial region A of the surface SA of the substrate S on which the precursor 5 is selectively adsorbed may be locally heated. Before the reactant supply operation (S40), the region-selective annealing operation using microwaves (S30) may be performed for a predetermined time until a desired annealing temperature is reached. The desired annealing temperature may be about 100 to about 600° C. By performing the region-selective annealing operation S30 using microwaves (MW), thermal damage to the substrate S that can be implemented as a device may be minimized, so that a semiconductor device having improved reliability can be provided. When region-selective annealing is performed by microwave MW, as compared to when annealing is performed by other methods, an annealing performing time may be relatively unrestricted.

A reactant supply operation (S40) of supplying a reactant gas into the chamber 10 may be performed. For example, in a state in which the reactant gas control valve 23 is opened and the gas outlet valve 25 is closed, a reactant gas may be supplied from a reactant storage unit 13 into the chamber 10.

The reactant gas may react with the precursor 5 adsorbed on the substrate S. In one example, the reactant gas may include a material such as a compound or molecule comprising oxygen such as H₂O, H₂O₂, O₂, or O₃. In one example, the reactant gas may include a material such as a compound comprising nitrogen and/or hydrogen, such as NH₃ or N₂H₄. The reactant gas may be stored in a liquid or gaseous state in the reactant storage unit 13. The reactant storage unit 13 may be heated and the reactant gas may be supplied into the chamber 10 at a predetermined vapor pressure. In the reactant supply operation (S40), the reactant gas may separate the ligands 2 of the precursor 5 from the central atom 1, thereby forming a thin film unit layer.

After the reactant supply operation (S40), a reactant purge operation (S50) of purging the chamber 10 may be performed. For example, by opening the purge gas control valve 22 and the gas outlet valve 25, purge gas in the purge gas storage unit 12 flows onto the surface SA of the substrate S so that excess reactant gas not reacted with the precursor, and reaction by-products generated by the reaction between the reactor gas and the precursor, may be removed.

The purge gas can be an inert gas, and the inert gas may include, for example, argon (Ar), nitrogen (N₂), or a combination thereof.

The method of manufacturing a thin film using the region-selective annealing process by microwave irradiation may set the above-described operations, that is, the precursor supply operation (S10), the precursor purge operation (S20), the region-selective annealing operation using microwaves (S30), the reactant supply operation (S4), and the reactant purge operation (S50) as a unit cycle process, and may include performing the unit cycle process a plurality of times. The unit cycle process may be repeatedly performed until a desired thin film thickness is reached. Thereafter, when a desired thin film thickness is reached, the substrate S on which the thin film is deposited may be unloaded from the chamber 10.

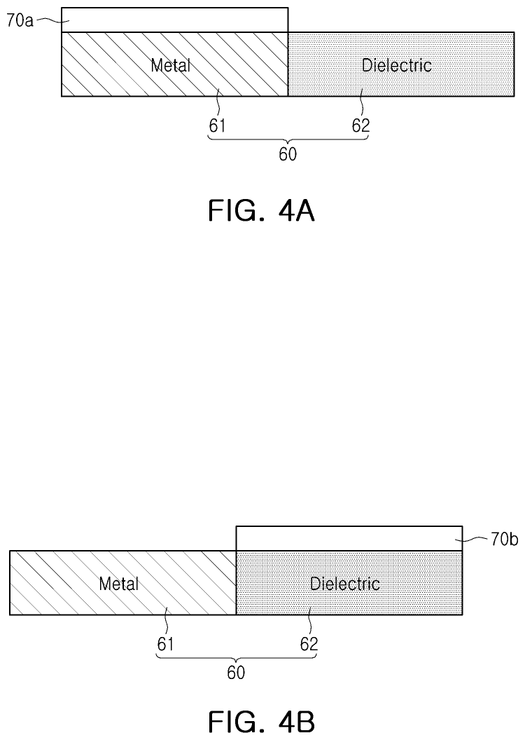

FIGS. 4A and 4B are diagrams illustrating an upper film, region-selectively formed on a lower film by an apparatus for manufacturing a thin film according to example embodiments.

Referring to FIG. 4A, an upper film 70a may be formed on a lower film 60, and the lower film 60 may include a metal film 61 and an insulating film 62, and an upper film 70a may be selectively deposited on the metal film 61 of the lower film 60. The upper film 70a may be a metal film or an insulating film. Forming the upper film 70a on the lower film 60 may include performing a region-selective atomic layer deposition process of metal on metal or a dielectric on metal. Forming the upper film 70a may include repeatedly performing the above-described unit cycle process a plurality of times. When the upper film 70a is formed, a region-selective annealing operation (S30 of FIG. 2) using microwaves may be performed.

Referring to FIG. 4B, an upper film 70b may be formed on a lower film 60, and the lower film 60 may include a metal film 61 and an insulating film 62, and the upper film 70b may be selectively deposited on the dielectric film 62 of the lower film 60. The upper film 70b may be an insulating film or a metal film. Forming the upper film 70b on the lower film 60 may include performing a region-selective atomic layer deposition process of a dielectric on dielectric or a metal on dielectric. Forming the upper film 70b may include repeatedly performing the above-described unit cycle process a plurality of times. When the upper film 70b is formed, a region-selective annealing operation (S30 of FIG. 2) using microwaves may be performed.

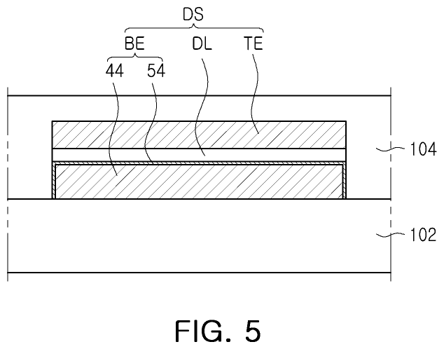

FIG. 5 is a cross-sectional view illustrating an information storage structure of a semiconductor device according to example embodiments.

Referring to FIG. 5, an information storage structure DS may be positioned on the semiconductor substrate 102. The information storage structure DS may include a lower electrode BE, a dielectric film DL, and an upper electrode TE.

The lower electrode BE may include a first conductive pattern 44 and a second conductive pattern 54 covering upper and side surfaces of the first conductive pattern 44. The second conductive pattern 54 may be thinner than the first conductive pattern 44.

The first conductive pattern 44 may include at least one of a polysilicon doped with impurities, a metal, a metal oxide film, and a metal nitride film. The first conductive pattern 44 may include, for example, a titanium nitride film (TiN).

The second conductive pattern 54 may include at least one of a metal, a metal oxide film, and a metal nitride film. The second conductive pattern 54 may include a metal different from that of the first conductive pattern 44. The second conductive pattern 54 may include, for example, at least one of a niobium nitride film (NbN), a molybdenum nitride film (MoN), a tantalum nitride film (TaN), ruthenium (Ru), platinum (Pt), and iridium (Ir). The second conductive pattern 54 is formed on the first conductive pattern 44 by a region-selective deposition method, and may be formed through a region-selective annealing operation (S30 of FIG. 2) using microwaves.

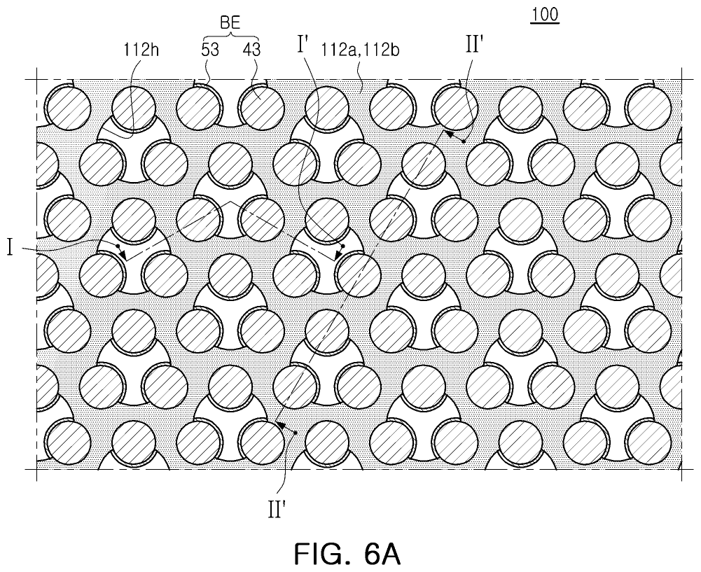

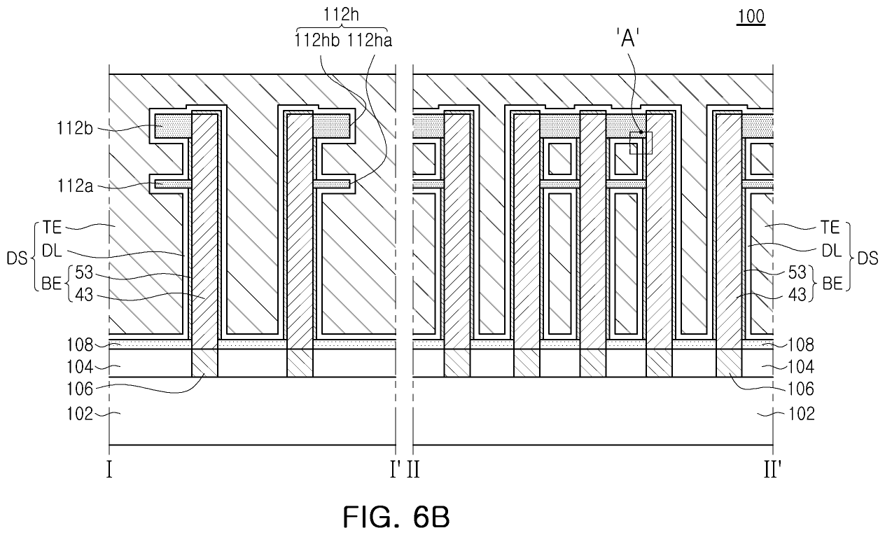

FIG. 6A is a plan view of a semiconductor device according to example embodiments, and FIG. 6B is a cross-sectional view of a semiconductor device according to example embodiments. FIG. 6B illustrates a cross-section taken along the cutting lines I-I′ and II-II′ of FIG. 6A.

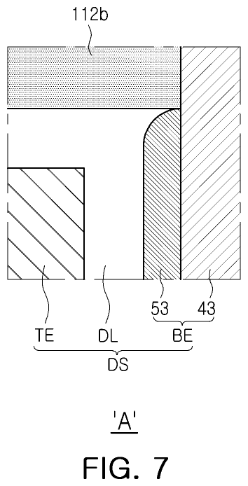

FIG. 7 is an enlarged view of area ‘A’ of FIG. 6B.

Referring to FIGS. 6A to 7, a semiconductor device 100 may include: a semiconductor substrate 102, contacts 106 on the semiconductor substrate 102, an etch stop film 108 and an information storage structure DS on the contacts 106, and support structures 112a and 112b supporting lower electrodes BE of the information storage structure DS.

The semiconductor substrate 102 may include a semiconductor material, such as a group IV semiconductor, a group III-V compound semiconductor, or a group II-VI compound semiconductor. For example, the group IV semiconductor may include silicon, germanium, or silicon-germanium. The semiconductor substrate 102 may be, for example, a silicon single crystal substrate.

A device isolation film may be disposed on the semiconductor substrate 102 to define or limit active regions. Word lines may be buried in the semiconductor substrate 102. The word lines may cross the active regions, and extend into the device isolation film. Impurity regions may be disposed in the semiconductor substrate 102 on both sides of the word lines. Bit lines may be electrically connected to each of the impurity regions on one side of the word lines. The contacts 106 may be electrically connected to the impurity regions on the other side of the word lines, respectively.

The contacts 106 may be disposed in an interlayer insulating film 104 disposed on the semiconductor substrate 102. The interlayer insulating film 104 may be formed of, for example, a silicon oxide film or a silicon nitride film. The contacts 106 may include at least one of polysilicon, a titanium nitride film, and tungsten, doped with impurities. The etch stop film 108 may be disposed on the interlayer insulating film 104. The etch stop film 108 may include, for example, at least one of a silicon nitride film, a silicon boron nitride film, a silicon carbon nitride film, and a silicon oxynitride film.

The information storage structure DS may include lower electrodes BE, an upper electrode TE on the lower electrodes BE, and a dielectric film DL between the lower electrodes BE and the upper electrode TE. Each of the lower electrodes BE may include a vertical conductive pattern 43 and a capping conductive film 53.

The vertical conductive pattern 43 may penetrate through the etch stop film 108 to contact the contacts 106, respectively. The vertical conductive pattern 43 may have a cylindrical shape or a hollow cylinder or cup shape. The vertical conductive pattern 43 may have a plug shape having a circular cross-section. The vertical conductive pattern 43 may be disposed to form a honeycomb shape in plan view. That is, six vertical conductive patterns 43 may be disposed to form a hexagon around one vertical conductive pattern 43. One side surfaces of the vertical conductive pattern 43 may be in contact with a first support pattern 112a and a second support pattern 112b. The vertical conductive pattern 43 may include at least one of polysilicon doped with impurities, a metal, a metal oxide layer, and a metal nitride layer.

The capping conductive film 53 may extend along a surface of the vertical conductive pattern 43. The capping conductive film 53 may be formed to have a substantially uniform thickness as a whole. However, as illustrated in FIG. 7, a thickness of the capping conductive film 53 may decrease toward a second support pattern 112b, by being adjacent to regions in which the second support pattern 112b and the vertical conductive pattern 43 are in contact with each other. Although not illustrated, the thickness of the capping conductive film 53 may decrease toward the first support pattern 112a. The capping conductive film 53 may be formed through a region-selective deposition process for selectively covering only surfaces of the lower electrodes BE, and a region-selective annealing process using microwaves. The capping conductive film 53 may include at least one of a metal, a metal oxide film, and a metal nitride film.

The dielectric film DL may cover surfaces of the lower electrodes BE and the support structures 112a and 112b with a uniform thickness. The dielectric film DL may include a high dielectric material, silicon oxide, silicon nitride, silicon oxynitride, or a combination thereof. However, in some example embodiments, the dielectric film DL may include an oxide, a nitride, a silicide, an oxynitride, or a silicified oxynitrides including one of hafnium (Hf), aluminum (Al), zirconium (Zr), titanium (Ti), neobium (Nb), tantalum (Ta), yttrium (Y), and lanthanum (La). The dielectric film DL may not be in contact with the vertical conductive pattern 43 and may be spaced apart from the vertical conductive pattern 43 by the capping conductive film 53.

The upper electrode TE may be disposed on the dielectric film DL. The upper electrode TE may extend along a surface of the dielectric film DL. The dielectric film DL may be disposed on the lower electrodes BE and the support structures 112a and 112b. The upper electrode TE may cover the dielectric film DL between the lower electrodes BE, and may be disposed to fill a space between the lower electrodes BE. The upper electrode TE may be formed of a single-film or multi-film structure of at least one of a titanium nitride film, tungsten, polysilicon doped with impurities, and silicon germanium layer doped with impurities. The upper electrode TE, dielectric film DL and lower electrode BE may form a metal-insulator-metal (MIM) capacitor in a random access memory device, such as a dynamic random access memory (DRAM) device. However the process including deposition with selective annealing as disclosed herein may be applied to the fabrication of other capacitors, such as MOM or MOS capacitors, or other memory devices such as a static random access memory (SRAM) device, a magnetic random access memory (MRAM) device, a NAND flash memory device, a high bandwidth memory (HBM) device, etc.

The support structures 112a and 112b may include a first support pattern 112a and a second support pattern 112b, spaced apart from each other. The second support pattern 112b may be disposed on the first support pattern 112a. The support structures 112a and 112b may be structures supporting the vertical conductive patterns 43 having a high aspect ratio. The first support pattern 112a and the second support pattern 112b may have different thicknesses. For example, the second support pattern 112b may be thicker than the first support pattern 112a. The first support pattern 112a and the second support pattern 112b may each have support holes 112h. The first support pattern 112a may have first support holes 112ha, and the second support pattern 112b may have second support holes 112hb. The first support holes 112ha and the second support holes 112hb may vertically overlap. The support holes 112h may expose side surfaces of the three vertical conductive patterns 43 adjacent to each other, respectively. The first support pattern 112a and the second support pattern 112b may be formed of a single-film or multi-film structure of at least one of a silicon nitride film, a silicon boron nitride film, and a silicon carbon nitride film. Surfaces of the vertical conductive patterns 43, not in contact with the support patterns 112a and 112b, may be covered with a capping conductive film 53, respectively. The capping conductive film 53 may in contact with side surfaces and upper surfaces of the vertical conductive patterns 43.

However, the capping conductive film 53 may be exposed without covering the support patterns 112a and 112b. In addition, the capping conductive film 53 may be exposed without covering the etch stop film 108. In addition, the capping conductive film 53 may be exposed without covering the etch stop film 108. The capping conductive film 53 may be exposed in a support hole 112h in FIG. 1 in a plan view.

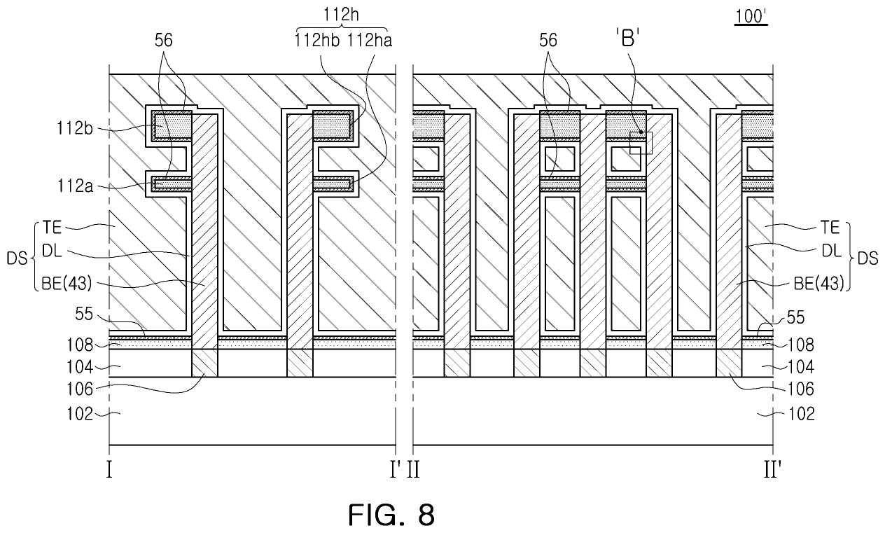

FIG. 8 is a cross-sectional view of a semiconductor device according to example embodiments.

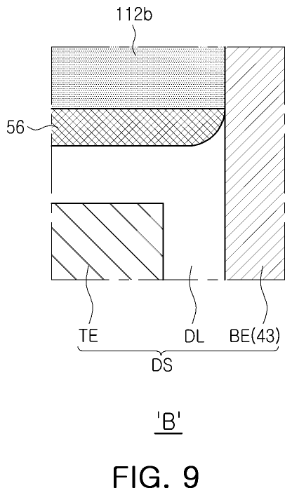

FIG. 9 is an enlarged view of area ‘B’ of FIG. 8.

Referring to FIGS. 8 and 9, a semiconductor device 100′ may be similar to the semiconductor device 100 of FIGS. 6A to 7, but may further include blocking films 55 and 56. The blocking films 55 and 56 may include a first blocking film 56 disposed between the first and second support patterns 112a and 112b and a dielectric film DL and a second blocking film 55 disposed between the etch stop film 108 and the dielectric film DL. The blocking films 55 and 56 may include a high-energy bandgap material. For example, the blocking films 55 and 56 may include a material having a larger energy bandgap than a material forming the support patterns 112a and 112b. Each of the blocking films 55 and 56 may include, for example, an aluminum oxide film, a zirconium oxide film, a lanthanum oxide film, a hafnium oxide film, a yttrium oxide film, a beryllium oxide film, a magnesium oxide film, a silicon oxide film, a hafnium silicon oxide film, a zirconium silicon oxide film, or a combination thereof. The blocking films 55 and 56 may be formed through a region-selective deposition process for selectively covering only surfaces of the support patterns 112a and 112b and a surface of the etch stop film 108, and a region-selective annealing process using microwaves.

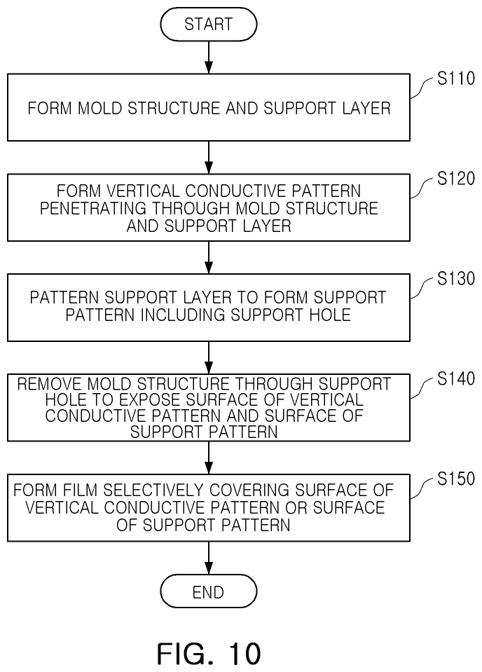

FIG. 10 is a flowchart illustrating a semiconductor device according to an example embodiment according to a process sequence.

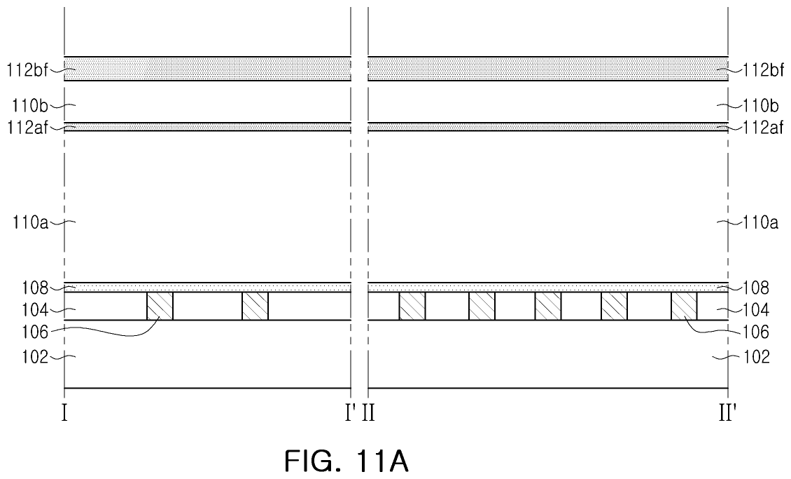

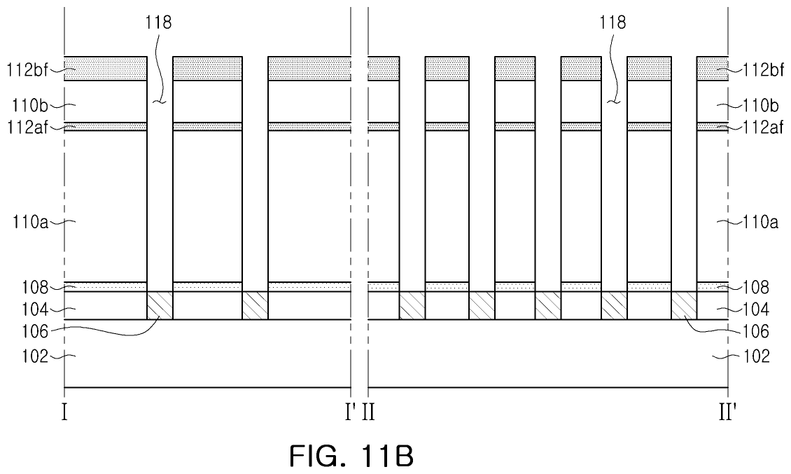

FIGS. 11A, 11B, 12A, 12B, 13A, 13B, 14, and 15 are diagrams illustrating a method of manufacturing a semiconductor device according to example embodiments.

Referring to FIGS. 10 and 11A, the method of manufacturing a semiconductor device may include an operation of forming a mold structure and a support layer (a first operation, S110). Before the first operation (S110), an interlayer insulating film 104 may be formed on a semiconductor substrate 102. Contacts 106 may be formed in the interlayer insulating film 104. An etch stop film 108 may be formed on the interlayer insulating film 104 and the contacts 106. In the first operation (S110), an etch stop film 108, mold structures 110a and 110b, and support layers 112af and 112bf may be formed (S110). The operation of forming the mold structures 110a and 110b and the support layers 112af and 112bf may include sequentially stacking the first mold film 110a, the first support film 112af, the second mold film 110b, and the second support film 112bf.

The first support film 112af and the second support film 112bf may be formed of the same material. The first mold film 110a and the second mold film 110b may include the same material, and may be formed of a material having etch selectivity to the first support film 112af and the second support film 112bf. For example, the first mold film 110a and the second mold film 110b may be formed of a silicon oxide film. The first support film 112af and the second support film 112bf may be formed of a single film or multiple films of at least one of a silicon nitride film, a silicon boron nitride film, and a silicon carbon nitride film. The first mold film 110a may be formed to be thicker than the second mold film 110b. The second support film 112bf may be formed to be thicker than the first support film 112af.

Referring to FIGS. 10, 11B, and 12B, a vertical conductive pattern penetrating through a mold structure and a support layer may be formed (second operation, S120). In the second operation, for example, lower electrode-holes 118 sequentially etching a second support film 112bf, a second mold film 110b, a first support film 112af, a first mold film 110a, and an etch stop film 108 to respectively expose the contacts 106 may be formed. A vertical conductive pattern 43 may be formed in the lower electrode-holes 118.

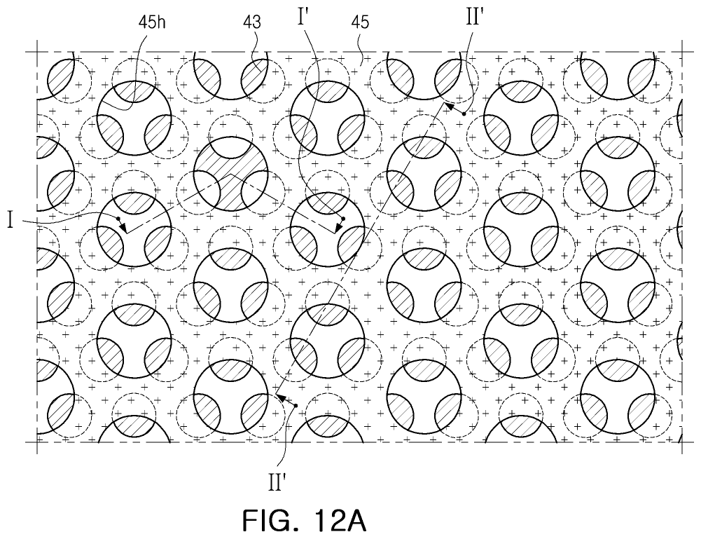

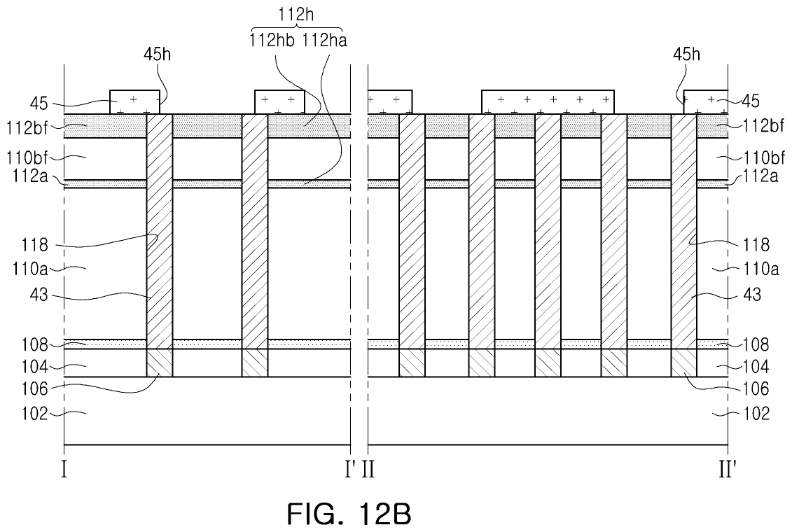

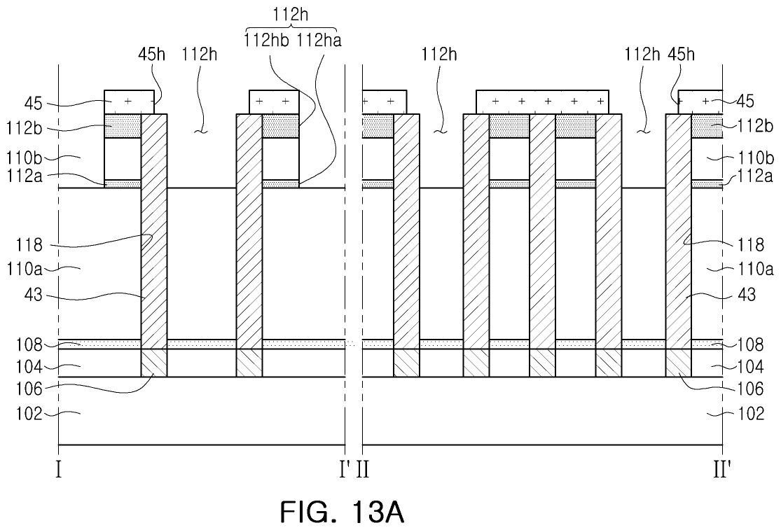

Referring to FIGS. 12A and 12B, a first mask pattern 45 may be formed on the second support layer 112bf. The first mask pattern 45 may include openings 45h partially exposing upper surfaces of the vertical conductive patterns 43. For example, the openings may partially expose upper surfaces of three adjacent vertical conductive patterns 43 and an upper surface of the second support layer 112bf therebetween.

Referring to FIGS. 10 to 13A, a support layer may be patterned to form a support pattern including a support hole (third operation S130). In the third operation S130, for example, using a first mask pattern 45 as an etching mask, an anisotropic etching process may be performed so that a second support film 112bf exposed by openings 45h, a second mold film 110b therebelow, and a first support film 112af therebelow, may be sequentially patterns, to form support holes 112h exposing an upper surface of the first mold film 110a. In this case, the first support layer 112af may be etched to form a first support pattern 112a having first support holes 112ha. In addition, the second support layer 112af may be etched to form a second support pattern 112b having second support holes 112hb. The first support holes 112ha may vertically overlap the second support holes 112hb, respectively, and may have the same/similar shape and size. In addition, in this case, a sidewall of the second mold film 110b may also be exposed.

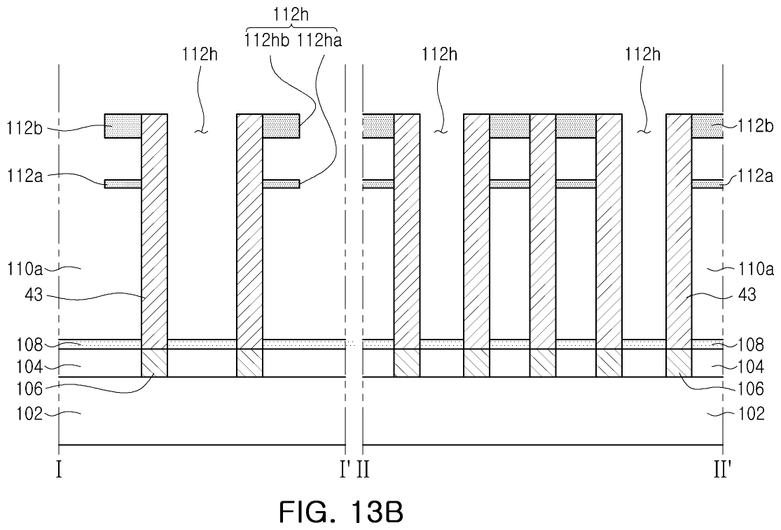

Referring to FIGS. 10 and 13B, a mold structure may be removed through a support hole and a surface of the vertical conductive pattern may be exposed (fourth operation, S140). In the fourth operation (S140), for example, by performing an isotropic etching process to remove a first mold film 110a and a second mold film 110b exposed by the support holes 112h, surfaces of a vertical conductive pattern 43 may be exposed. In this case, an upper surface of the etch stop film 108 and upper surfaces, side surfaces, and lower surfaces of the first support pattern 112a and the second support pattern 112b may be exposed.

Alternatively, after etching the second support film 112bf by an anisotropic process, a second support pattern 112b including the second support hole 112hb may be formed, and then a second mold film 110bf may be removed through the second support hole 112hb by an isotropic etching process. Thereafter, the first support film 112af may be etched by an anisotropic etching process to form a first support pattern 112a including a first support hole 112ha, and a first mold film 110bf may be removed through the first support hole 112ha by an isotropic etching process.

Referring to FIGS. 10, 14, and 15, a film selectively covering a surface of the vertical conductive pattern or a surface of the support pattern may be formed (fifth operation, S150). In the fifth operation (S150), a region-selective deposition (ASD) process is performed, and a region-selective annealing operation using microwaves (S30 in FIG. 2) may also be performed.

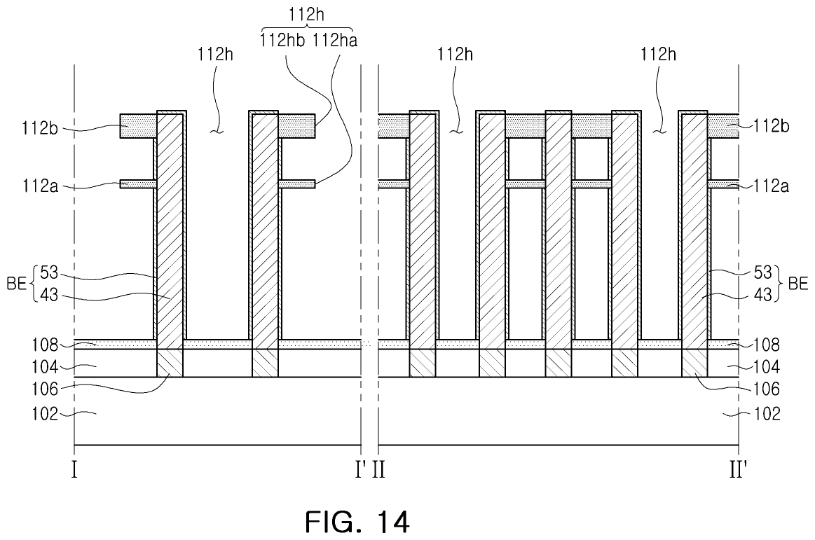

As illustrated in FIG. 14, the region-selective deposition process may be performed using a specific precursor material having no or relatively low chemical affinity with the surfaces of the etch stop film 108, the first support pattern 112a, and the second support pattern 112b. On the other hand, the region-selective deposition process may be performed using the specific precursor material having relatively high chemical affinity with the surfaces of the vertical conductive patterns 43. After the precursor material is adsorbed on the surface of the vertical conductive pattern 43, a region-selective annealing operation may be performed by irradiating the precursor material with microwaves for inducing vibrations. Accordingly, in the fifth operation (S150), a film (capping conductive film 53) selectively covering the surface of the vertical conductive pattern 43 may be formed.

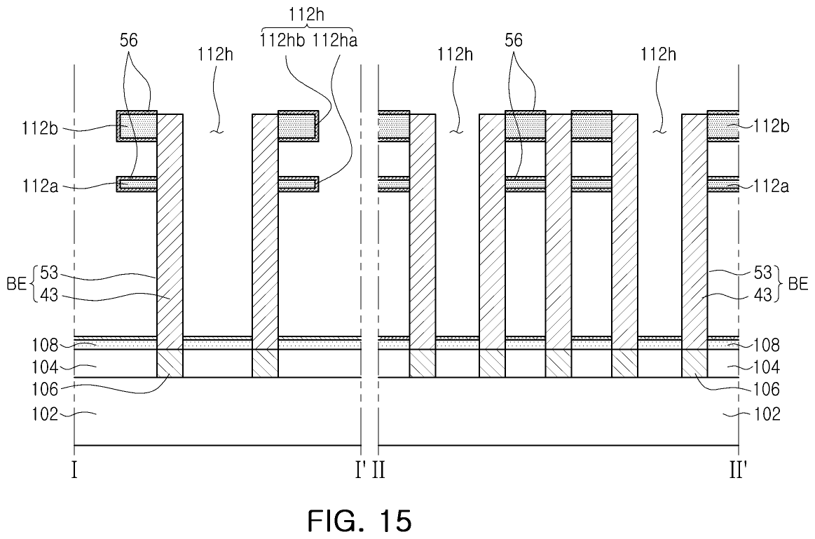

As illustrated in FIG. 15, the region-selective deposition process may be performed using a specific precursor material having no or relatively very small (low) chemical affinity with the surfaces of the vertical conductive patterns 43. On the other hand, the region-selective deposition process may be performed using the specific precursor material having relatively high (high) chemical affinity with the surfaces of the etch stop film 108, the first support pattern 112a, and the second support pattern 112b. After adsorbing the precursor material on the surface of each of the etch stop film 108, the first support pattern 112a, and the second support pattern 112b, a region-selective annealing operation by irradiating the precursor material with microwaves for inducing vibrations can be performed. Accordingly, in the fifth operation (S150), a first blocking film 55 selectively covering the surface of the etch stop film 108 and a second blocking film 56 selectively covering the surface of each of the first support pattern 112a and the second support pattern 112b may be formed.

In FIGS. 5 to 15, it has been exemplarily described that the region-selective annealing using microwaves can be performed when an information storage structure of a semiconductor device is formed, but an example embodiment of the present inventive concept is not limited thereto. It may also be applied when forming various elements, insulating films, or interconnections that can be formed in or on a substrate.

In FIGS. 5 to 15, it has been exemplarily described that the region-selective annealing using microwaves can be performed when an information storage structure of a semiconductor device is formed, but an example embodiment of the present inventive concept is not limited thereto. It may also be applied when forming various elements, insulating films, or interconnections that can be formed in or on a substrate.

As set forth above, by forming a thin film by using a region-selective annealing process by microwave irradiation, thermal damage to a substrate that can be implemented as a device may be minimized, so that a semiconductor device having a simple manufacturing process and improved reliability may be provided.

Herein, a lower side, a lower portion, a lower surface, and the like, are used to refer to a direction toward a mounting surface of the fan-out semiconductor package in relation to cross sections of the drawings, while an upper side, an upper portion, an upper surface, and the like, are used to refer to an opposite direction to the direction. However, these directions are defined for convenience of explanation, and the claims are not particularly limited by the directions defined as described above.

The meaning of a “connection” of a component to another component in the description includes an indirect connection through an adhesive layer as well as a direct connection between two components. In addition, “electrically connected” conceptually includes a physical connection and a physical disconnection. It can be understood that when an element is referred to with terms such as “first” and “second”, the element is not limited thereby. They may be used only for a purpose of distinguishing the element from the other elements, and may not limit the sequence or importance of the elements. In some cases, a first element may be referred to as a second element without departing from the scope of the claims set forth herein. Similarly, a second element may also be referred to as a first element.

The term “an example embodiment” used herein does not refer to the same example embodiment, and is provided to emphasize a particular feature or characteristic different from that of another example embodiment. However, example embodiments provided herein are considered to be able to be implemented by being combined in whole or in part one with one another. For example, one element described in a particular example embodiment, even if it is not described in another example embodiment, may be understood as a description related to another example embodiment, unless an opposite or contradictory description is provided therein.

Terms used herein are used only in order to describe an example embodiment rather than limiting the present disclosure. In this case, singular forms include plural forms unless interpreted otherwise in context.

While example embodiments have been shown and described above, it will be apparent to those skilled in the art that modifications and variations could be made without departing from the scope of the present inventive concept as defined by the appended claims.

What is claimed is:

1. A method of forming a thin film, comprising:
supplying a precursor to a substrate, to selectively adsorb the precursor to a partial region of a surface of the substrate;
performing a region-selective annealing by irradiating microwaves onto the substrate; and
supplying a reactant to react with the precursor adsorbed on the substrate to form a thin film unit layer,
wherein the microwaves irradiated onto the substrate induce vibrations in at least a portion of the precursor so that the partial region of the surface of the substrate on which the precursor is adsorbed is locally heated.

2. The method of claim 1, wherein the precursor comprises a central atom and at least one ligand bound to the central atom.

3. The method of claim 2, wherein, in the performing the region-selective annealing, the at least one ligand of the precursor is vibrated by the microwaves.

4. The method of claim 2, wherein the precursor comprises at least one of a monomer precursor having one of the central atom and a dimer precursor having two of the central atom.

5. The method of claim 2, wherein the central atom comprises a metal,
wherein the at least one ligand comprises a polar molecule or ion.

6. The method of claim 1, wherein the microwaves comprise electromagnetic waves having a frequency in a range of about 0.3 GHz to about 300 GHz.

7. The method of claim 1, further comprising:
purging an excess precursor, not adsorbed on the surface of the substrate; and
purging an excess reactant not reacted with the precursor.

8. The method of claim 1, wherein, before the supplying the reactant, the supplying the precursor to the substrate to selectively adsorb the precursor to the partial region of the surface of the substrate is performed at least one additional time.

9. The method of claim 1, wherein, before the supplying of the reactant, the performing of the region-selective annealing by irradiating microwaves onto the substrate is performed for a predetermined time until a desired annealing temperature is reached.

10. A method of forming a thin film, comprising:
supplying a precursor to a substrate positioned in a chamber in a precursor supply operation;
purging the chamber in a precursor purge operation after the precursor supply operation;
locally heating a region of a surface of the substrate on which the precursor is selectively adsorbed by irradiating microwaves into the chamber in a region selective annealing operation; and
supplying a reactant to the chamber to react with the precursor adsorbed on the substrate in a reactant supply operation; and
purging the chamber of reactant in a reactant purge operation;
wherein the precursor supply operation, the precursor purge operation, the region-selective annealing operation, the reactant supply operation and the reactant purge operation together form at least in part a unit cycle process, which unit cycle process is performed multiple times.

11. The method of claim 10, wherein, when the unit cycle process is performed once, the precursor supply operation is performed a plurality of times.

12. The method of claim 10, wherein, in the region-selective annealing operation, the other region of the surface of the substrate on which the precursor is not adsorbed is not heated.

13. The method of claim 10, wherein the precursor comprises a central atom and at least one ligand bound to the central atom.

14. The method of claim 13, wherein, in the region-selective annealing operation, the at least one ligand of the precursor is vibrated by the microwaves.

15. The method of claim 10, further comprising:
loading the substrate into the chamber in a loading operation before performing the unit cycle process; and
unloading the substrate on which the thin film is deposited from the chamber in an unloading operation, when a desired thickness of the thin film is formed by repeatedly performing the unit cycle process a plurality of times.

16. A method of manufacturing a semiconductor device, comprising:
forming a lower film; and
region-selectively forming an upper film on the lower film,
wherein the forming the upper film includes repeatedly performing a unit cycle process a plurality of times,
wherein the unit cycle process includes
a precursor supply operation of supplying a precursor to the lower film, to adsorb the precursor to a partial region of a surface of the lower film;
a region-selective annealing operation of locally heating the region of the surface of the lower film on which the precursor is adsorbed, by irradiating microwaves to induce vibrations in at least a portion of the precursor; and
an operation of supplying a reactant to react with the precursor to form a thin film unit layer of the upper film.

17. The method of claim 16, wherein the precursor comprises a central atom and at least one ligand bound to the central atom,
wherein the precursor comprises at least one of a monomer precursor having one of the central atom and a dimer precursor having two of the central atom.

18. The method of claim 16, further comprising:
forming a vertical conductive pattern and a support pattern supporting the vertical conductive pattern;
forming a dielectric film on the vertical conductive pattern and the support pattern; and
forming an upper electrode on the dielectric film,
wherein the lower film is the vertical conductive pattern or the support pattern,
wherein the upper film is a film selectively formed on a surface of the vertical conductive pattern or a surface of the support pattern.

19. The method of claim 16, wherein the region-selectively forming the upper film on the lower film is an atomic layer deposition of metal on metal or dielectric on dielectric.

20. The method of claim 16, wherein the region-selectively forming the upper film on the lower film is an atomic layer deposition of a dielectric on metal or a metal on dielectric.
